(19) United States
(12) Patent Application Publication
(10) Pub. No.: US 2003/0040152 A1
(43) Pub. Date: Feb. 27, 2003

(54) Method of fabricating a NROM cell to prevent charging

(76) Inventors: Chen-Chin Liu, Yun-Lin Hsien (TW); Jiann-Long Sung, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,337

(22) Filed: Aug. 22, 2001

(51) Int. Cl. H01L 21/8242; H01L 21/8236

(52) U.S. Cl. 438/239; 438/241; 438/276; 438/262

(57) ABSTRACT

The present invention provides a method of fabricating an NROM cell and preventing charging. An oxide-nitride-oxide (ONO) layer and bit line masks are formed on the ONO layer of the memory array area and an implantation process forms buried bit lines within the substrate. Rows of word lines can then be formed on the ONO layer approximately perpendicular to the buried bit lines. Finally, a spacer is formed on sidewalls of each word line, and a barrier layer and a passivation layer used for preventing the NROM cell being charged during process is respectively formed on the surface of the substrate.

### BACKGROUND OF INVENTION

1. Field of the Invention

The present invention relates to a method of fabricating a nitride read only memory (NROM) cell.

2. Description of the Prior Art

Nitride read only memory (NROM), comprising a plurality of memory cells, is used to store data. Each memory cell is composed of a MOS transistor and a silicon nitride layer. Since the silicon nitride layer has a high density, hot electrons tunnel through the MOS transistor to become trapped in the silicon nitride layer, thus achieving information storage.

Please refer to FIG. 1 to FIG. 5. FIG. 1 to FIG. 5 are schematic diagrams of a prior art of fabricating a NROM cell. As shown in FIG. 1, the NROM cell is formed on a silicon substrate 12. The silicon substrate 12 is a P-type silicon substrate and comprises a memory array region for storing electrons and a periphery circuit region for controlling the logic circuits. A first step of the prior method is to perform a conventional oxide-nitride-oxide (ONO) process to form an ONO layer 19 on the surface of the silicon substrate 12. The ONO layer 19 comprises a bottom oxide layer 14, a silicon nitride layer 16 and a top oxide layer 18. Following this, a photoresist layer 20 is formed on the ONO layer 19 followed by a photolithographic and etching process to define patterns of a bit line in the photoresist layer 20.

As shown in FIG. 2, using the patterned photoresist layer 20 as a mask, a dry etching process is performed to remove the top oxide layer 18 and the silicon nitride layer 16. An ion implantation process with a direction 22 is then performed to form a plurality of doped areas 24 within the silicon substrate 12. The doped areas 24 function as a bit line or a buried drain. Thereafter, the photoresist layer 20 is completely removed.

As shown in FIG. 3, a thermal oxidation process is performed to form a field oxide layer 26 on the surface of the bit line 24 to isolate two silicon nitride layers 16 from each other. Finally, as shown in FIG. 4, a doped polysilicon layer 28 is deposited as a word line.

After formation of the word line of the NROM device according to prior art, a passivation layer 29 is formed over each word line for preventing the device from experiencing UV light irradiation or plasma damage in subsequent chemical vapor deposition (CVD) or etching processes and a spacer 27 is formed on sidewalls of each word line, as shown in FIG. 5. However, the passivation layer 29 directly contacts the ONO layer 19 of the NROM. Therefore, portions of ionized electrons formed by UV light irradiation in subsequent chemical vapor deposition (CVD) or etching processes pass through the passivation layer 29 into the ONO layer 19 and affect the electrical performance of the NROM.

### SUMMARY OF INVENTION

It is therefore a primary objective of the present invention to provide an improved fabricating method of an NROM for preventing the NROM from UV light irradiation or plasma damage in subsequent processes.

In accordance with the claim invention, a substrate comprising a memory array area and a periphery circuit region is first provided. An oxide-nitride-oxide (ONO) layer comprising a bottom oxide layer, a silicon nitride layer and a top oxide layer is formed on the surface of the substrate. Thena plurality of columns of bit line masks are formed on the ONO layer of the memory array area followed by performing a first ion implantation process to form a plurality of buried bit lines within the substrate not covered by the bit line masks. After removing the bit line mask, a plurality of rows of word lines is formed on the ONO layer approximately perpendicular to the buried bit lines. Finally, a sacrificial layer is formed on the substrate, and an etching-back process is performed on the sacrificial layer to form a spacer on sidewalls of each word line followed by respectively forming a barrier layer and a passivation layer on the surface of the substrate.

Since a barrier layer and a passivation layer are respectively formed on the surface of the NROM manufactured by the present invention, the NROM is prevented from UV light irradiation or plasma damage in subsequent processes. As well, the barrier layer can effectively separate the passivation layer and the ONO layer of the NROM for preventing the passivation layer directly contacting with the ONO layer. Furthermore, the ionized electrons within the passivation layer are suppressed to get into the ONO layer affecting the electrical performance of the NROM.

### BRIEF DESCRIPTION OF DRAWINGS

FIG. 1 to FIG. 5 are schematic diagrams of a prior art of fabricating a NROM cell.

FIG. 6 to FIG. 10 are schematic diagrams of a method of fabricating a NROM cell according to the present invention.

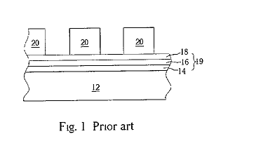

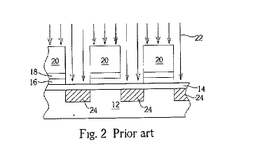

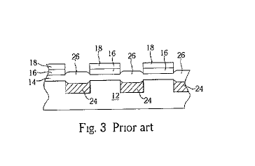

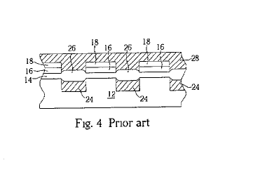

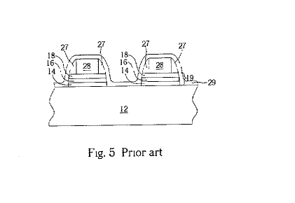

### DETAILED DESCRIPTION

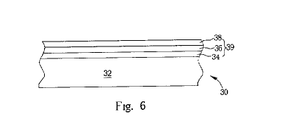

Please refer to FIG. 6 to FIG. 10. FIG. 6 to FIG. 10 are schematic diagrams of a method of fabricating a NROM cell according to the present invention. As shown in FIG. 6, the NROM cell is formed on a substrate 32 of a semiconductor wafer 30. The substrate 32 comprises a memory array region and a periphery circuit region. In a better embodiment of the present invention, the substrate 32 is a P-type silicon substrate. Alternatively, the substrate 32 can be a silicon-on-insulator (SOI) substrate. To specify the main features of the present invention, only a cross-sectional view of the NROM cell within the memory array region is shown in FIG. 6 to FIG. 10. As shown in FIG. 6, an ONO layer 39 with a thickness of 150 to 250 angstroms is formed on the surface of the substrate 32. The ONO layer 39 is composed of a bottom oxide layer 34 with a thickness between 50 and 150 angstroms, a silicon nitride layer 36 with a thickness between 20 and 150 angstroms, and a top oxide layer 38 with a thickness between 50 and 150 angstroms.

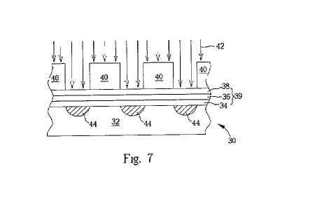

Next, three steps are performed to adjust the threshold voltage in the periphery circuit region. First, a mask (not shown) is formed on the ONO layer 39 in the memory array region. Then, an ion implantation process is performed to adjust dopant concentration of the substrate 32 not covered by the mask, and finally the mask is removed. As shown in FIG. 7, a photoresist layer 40 is formed on the ONO layer 39 followed by a photolithographic and etching process to define patterns of a bit line in the photoresist layer 40. A plurality of columns of bit line masks is thus formed using the patterned photoresist layer 40. Then, an ion implantation process with a direction 42 is performed to implant arsenic (As) ions or the other N-type dopants into the substrate 32 not covered by the photoresist layer 40. Thus, a plurality of N-doped areas 44 is formed within the substrate 32 as a buried bit line of the memory cell. In the ion implantation process 42, the implant dosage of the As ions is approximately 1E15 to 1E16 atoms/cm² while the implant energy of the As ions is approximately 20 to 80 KeV. A preferred implant energy for the As ions is suggested as 50 KeV.

Subsequently, a rapid thermal annealing process is performed at a temperature of 800 to 1000° C. to activate dopants in the substrate 32. Thereafter, the photoresist layer 40 is completely removed.

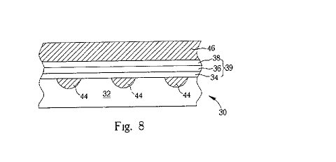

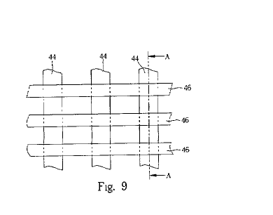

As shown in FIG. 8, a doped polysilicon layer 46 is deposited on the surface of the semiconductor wafer 30 as a word line. After the deposition process, a plurality of rows of word lines 46 is formed on the semiconductor wafer 30 approximately perpendicular to the doped area 44 (bit lines), as shown in FIG. 9.

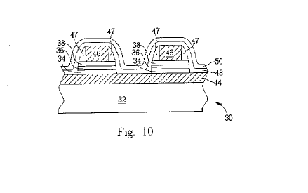

Finally as shown in FIG. 10 of a cross-sectional diagram along line A—A shown in FIG. 9. A sacrificial layer (not shown) composed of silicon nitride is formed on the surface of the substrate 32 followed by etching back the sacrificial layer down to the surface of the substrate 32 for forming a spacer 47 on sidewalls of each word line. Finally, a barrier layer 48 composed of silicon oxide and a passivation layer 50 composed of silicon nitride are respectively formed on the surface of the substrate 32. The passivation layer 50 is used to prevent the NROM from UV light irradiation or plasma damage in subsequent processes, and the barrier layer 48 formed between the passivation layer 50 and the NROM is used to isolate the passivation layer 50 and the silicon nitride layer 36 from each other. Furthermore, the ionized electrons formed by UV light irradiation in subsequent chemical vapor deposition (CVD) or etching processes are suppressed to pass through the passivation layer 50 into the ONO layer 39 affecting the electrical properties of the NROM.

In contrast to the prior art method of forming a NROM cell, the present invention uses a CVD method to form a barrier layer which separates the passivation layer and the ONO layer of the NROM. The passivation layer may generate ionized electrons by UV light irradiation in subsequent CVD or etching processes, so the barrier layer prevents the ionized electrons in the passivation layer getting into the ONO layer. Therefore, the NROM cell avoids being charged during process, and the endurance and reliability of the NROM will be improved.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a nitride read only memory (NROM) cell and preventing charging comprising:
providing a substrate comprising a memory array area and a periphery circuit region;
forming a oxide-nitride-oxide (ONO) layer on the surface of the substrate, the ONO layer comprising a bottom oxide layer, a silicon nitride layer and a top oxide layer;
forming a plurality of columns of bit line masks on the ONO layer of the memory array area;
performing a first ion implantation process to form a plurality of buried bit lines within the substrate not covered by the bit line masks;
removing the bit line masks;
forming a plurality of rows of word lines on the ONO layer, the word lines being approximately perpendicular to the buried bit lines;
forming a sacrificial layer on the substrate and etching back the sacrificial layer down to the surface of the substrate to form a spacer on sidewalls of each word line; and
forming a barrier layer and a passivation layer respectively on the surface of the substrate.

2. The method of claim 1 wherein prior to forming a plurality of the bit line masks the method further comprises:
forming at least one mask on the ONO layer of the memory array area;
performing a second ion implantation process to adjust a dopant concentration of the substrate not covered by the mask; and
removing the mask.

3. The method of claim 1 wherein the thickness of the bottom oxide layer is between 50 to 150 angstroms (Å), the thickness of the silicon nitride layer is between 20 to 150 angstroms (Å), and the thickness of the top oxide layer is between 50 to 150 angstroms (Å).

4. The method of claim 1 wherein the bit line masks comprise photoresist materials.

5.The method of claim 1 wherein the substrate is a silicon substrate or a silicon-on-insulator (SOI) substrate.

6. The method of claim 1 wherein the sacrificial layer comprises silicon nitride.

7. The method of claim 1 wherein the passivation layer is used to prevent the NROM from UV light irradiation or plasma damage in subsequent processes.

8. The method of claim 7 wherein the passivation layer comprises silicon nitride.

9. The method of claim 1 wherein the barrier layer is used to prevent influencing the electrical properties of the NROM due to the contact between the passivation layer and the silicon nitride layer which results in the NROM being charged during process.

10. The method of claim 9 wherein the barrier layer comprises silicon oxide.
